(19) United States
(12) Patent Application Publication
(10) Pub. No.: US 2008/0238259 A1
(43) Pub. Date: Oct. 2, 2008

(54) ULTRASONIC PROBE AND PRODUCTION METHOD THEREOF

(75) Inventor: Atsushi Osawa, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/060,535

(22) Filed: Apr. 1, 2008

(30) Foreign Application Priority Data
Apr. 2, 2007 (JP) 2007-096199
Sep. 28, 2007 (JP) 2007-255327

(51) Int. Cl. H01L 41/083; H01L 41/22

(52) U.S. Cl. 310/334; 216/18

(57) ABSTRACT

An ultrasonic probe realizing a high sensitivity and a wide band thereof while miniaturizing a transducer and also taking into consideration a measure against generated heat. The ultrasonic probe includes: a backing material; a transducer array having a multi-layered structure in which a plurality of transducers are arranged in a first direction to compose a transducer group and a plurality of the transducer groups are arranged in a second direction different from the first direction; a first layer of conductive resin electrically connecting the first electrode layers of adjacent transducers with each other in each transducer group; a second layer of conductive resin electrically connecting the internal electrode layers of adjacent transducers with each other in each transducer group; and an insulating resin disposed in a predetermined region among the plurality of transducers in each transducer group.

### BACKGROUND OF THE INVENTION

1. Field of the Invention

The present invention relates to an ultrasonic probe to be used for transmitting and receiving ultrasonic waves in an ultrasonic diagnosing apparatus, and further relates to a production method of such an ultrasonic probe.

2. Description of a Related Art

In an ultrasonic probe, a transducer of a piezoelectric material (piezoelectric transducer) having electrodes formed at both ends thereof is used as an ultrasonic transducer for transmitting and/or receiving ultrasonic waves. The piezoelectric material is generally made of piezoelectric ceramic represented by PZT (Pb(lead) zirconate titanate), polymer piezoelectric material represented by PVDF (polyvinyliden difluoride), or the like.

When a voltage is applied across the electrodes of such a transducer, the piezoelectric material expands and contracts by the piezoelectric effect to generate an elastic wave. In particular, a wide band signal voltage applied across the electrodes of the transducer generates a resonant elastic wave having a wavelength depending on the thickness of the piezoelectric material. In a particular case in which the thickness of the ceramic piezoelectric material is not more than several millimeters, the piezoelectric material generates ultrasonic waves. Further, by arranging a plurality of transducers in one dimensional manner or two dimensional manner and driving the transducers with drive signals having predetermined respective delays, it is possible to form a beam of ultrasonic waves directed toward a desired direction. On the other hand, the transducers expand and contract by receiving propagated ultrasonic waves, and thereby generate electric signals. The electric signals are used as detection signals of the ultrasonic waves.

An ultrasonic diagnosing apparatus, using the ultrasonic probe, transmits ultrasonic waves to an object to be inspected such as a human body and receives ultrasonic echoes reflected from the object, and thereby displays an image based on the detection signals of the ultrasonic waves. In this manner, inspection of an organ or a blood vessel inside of the body can be carried out. When the piezoelectric ceramic is used for the transducer, however, there is a great difference in an acoustic impedance between the transducer and the human body or the like, and a reflection of the ultrasonic waves is caused at a boundary face having such an acoustic impedance difference, resulting in a propagation loss.

Here, the acoustic impedance is a constant value specific to a material and represented by a product of an acoustic medium density and an acoustic velocity, and a mega-Rayl (MRayl) is generally used for a unit thereof (1 MRayl=1×10⁶ kg·m⁻² ·s⁻¹). The acoustic impedance of typical piezoelectric ceramic is about 25 MRayl to about 35Mrayl, and the acoustic impedance of the human body is about 1.5 MRayl.

When the acoustic impedance of the transducer is denoted by Z_{O} and the acoustic impedance of the human body is denoted by Z_{M}, a reflectance R of an ultrasonic wave at a contact interface is given by the following formula (1).

R=|Z_{O}−Z_{M}|/(Z_{O}+Z_{M}) (1)

When Z_{O}=35 MRayl and Z_{M}=1.5 MRayl in the formula (I), R=0.92 and thereby almost all the ultrasonic wave is reflected at the contact interface and only less than ten percent of the ultrasonic wave is propagated.

In order to solve this problem, acoustic impedance matching is carried out by inserting an acoustic matching layer between the transducer and the object to be inspected. Further, the propagation efficiency of the ultrasonic wave can be improved by causing the acoustic matching layer to have a multi-layered structure. However, the number of the acoustic matching layers is limited to two or three for convenience in production thereof.

Accordingly, it is considered to reduce the acoustic impedance of the transducer itself for further improving the propagation efficiency of the ultrasonic wave. For example, it is effective to form a matrix of grooves in the piezoelectric material to form the piezoelectric material into an array and to fill the grooves with material having an acoustic impedance of about 2 MRayl to 4 MRayl. Here, a spacing of the grooves is made sufficiently small compared with a wavelength of an acoustic wave propagating inside of each transducer separated by the grooves. Generally, it is preferable to make the spacing of the grooves about ⅛ to 1/10 of the wavelength of the ultrasonic wave. For such an array transducer, there is used a composite piezoelectric material made of PZT rods having a long dimension in one direction arranged in resin, for example, and this composite piezoelectric material is called 1-3 composite.

In a case of the 1-3 composite, each transducer has a rod shape, and a vibration mode thereof becomes a 33-vibration mode. The 33-vibration mode means a vibration mode when a piezoelectric material subjected to polarization processing (polling processing) in a third direction (Z-axis direction) is vibrated by an electric field applied in the same third direction. Generally, in transducers, an electromechanical coupling coefficient k33 of the 33-vibration mode is larger than an electromechanical coupling coefficient kt of a plate shape or an electromechanical coupling coefficient k33′ of a bar shape, and a high conversion efficiency is expected to be obtained by making each transducer have a rod shape.

Also, a large value of the electromechanical coupling coefficient k33 contributes to an increase in a bandwidth of the transducer. Further, by employing the 1-3 composite, a part of a piezoelectric material having a high acoustic impedance is replaced with resin having a low acoustic impedance, and therefore, it is possible to reduce an acoustic impedance of the transducer and improve the propagation efficiency of the ultrasonic wave. Note that, by the reduction of an effective area of the piezoelectric material having a large dielectric constant, a capacitance of the transducer is reduced and electrical impedance is increased in electrical characteristics thereof.

As a related technology, Japanese Patent Application Publication JP-P2003-70096A discloses an ultrasonic probe using a composite piezoelectric material with a fine structure to have a high reliability and a low cost. In the composite piezoelectric material, a plurality of composite sheets, each of which has a plurality of fine-wire sintered piezoelectric materials arranged in one direction on the surface of a resin layer, is stacked and integrated such that the fine-wire sintered piezoelectric materials are sandwiched between the resin layers, and the integrated piezoelectric material is cut in the direction perpendicular to the longitudinal direction of the fine-wire sintered piezoelectric materials.

Also, Japanese Patent Application Publication JP-P2003-174698A discloses a production method of a composite piezoelectric material accommodated to an ultrasonic vibration in a high frequency band. In this production method, a unit composite sheet is formed, and the composite piezoelectric material is formed by stacking this unit composite sheet. The production method of the unit composite sheet includes the steps of preparing a composite plate having a resin layer formed on a surface of a plate piezoelectric material, and forming a plurality of fine-wire piezoelectric materials from the plate piezoelectric material by forming a plurality of grooves in the plate piezoelectric material of the composite plate without cutting the resin layer completely.

Further, Japanese Patent Application Publication JP-P2003-189395A discloses a production method of a composite piezoelectric material which method can provide a composite piezoelectric material having a plurality of fine-pillar piezoelectric materials with a high aspect ratio and a small electrical impedance at a low cost without degrading a performance thereof. The production method includes the steps of preparing a composite plate, which has a plurality of piezoelectric materials and a plurality of conductive materials arranged alternately extending in one direction, on a resin layer, and forming a plurality of grooves, which extend in a direction crossing the longitudinal direction of the piezoelectric materials, in the plate piezoelectric material of the composite plate to form a plurality of pillar piezoelectric materials and a plurality of internal conductive materials extending across the plurality of pillar piezoelectric materials on the resin layer.

Meanwhile, recently, the ultrasonic probe is used for an endoscope to be inserted from a mouth into a body (peroral endoscope), an endoscope to be inserted from a nose into a body (nasal endoscope), a blood vessel catheter or the like, and the ultrasonic probe is desired to be miniaturized. The diameter of the peroral endoscope is about 8 mm to 11 mm and the diameter of the nasal endoscope is about 4 mm to 5 mm, and therefore, the size of the transducer needs to be smaller. For example, the size in the elevation direction of a convex-type array transducer for FNA (fine needle aspiration) is about 4 mm to 5 mm.

However, the electrical impedance of the transducer increases along with the miniaturization thereof. When the electrical impedance of the transducer in a frequency band of a ultrasonic wave to be transmitted and received is larger than an electrical impedance of a reception circuit in an ultrasonic diagnosing apparatus main body or a characteristic impedance of a connection cable, transmission characteristics of the detection signal is degraded. Also due to reduction in size of a transducer, receiving sensitivity is degraded.

For compensating such sensitivity reduction, the capacitance of the transducer is sometimes increased to reduce the electrical impedance by making the transducer have a multi-layered structure in which transducers of respective layers are connected in parallel.

### SUMMARY OF THE INVENTION

The present invention has been achieved in view of such problems. An object of the present invention is to provide an ultrasonic prove realizing a high sensitivity and a wide band thereof while miniaturizing the transducer and also taking into consideration a measure against generated heat.

For achieving the above objects, an ultrasonic probe according to one aspect of the present invention is an ultrasonic probe including a plurality of transducers for transmitting and/or receiving ultrasonic waves, and the ultrasonic probe includes: (i) a backing material; (ii) a transducer array in which a plurality of transducers are arranged in a first direction to compose a transducer group and the plurality of transducer groups are arranged in a second direction different from the first direction, each transducer having a multi-layered structure including: a first electrode layer formed on a principal surface of the backing material, a plurality of piezoelectric layers, at least one internal electrode layer, and a second electrode layer common in each transducer group; (iii) a first layer of conductive resin electrically connecting the first electrode layers of adjacent transducers with each other in each transducer group; (iv) a second layer of conductive resin electrically connecting the internal electrode layers of adjacent transducers with each other in each transducer group; and (v) an insulating resin disposed in a predetermined region among the plurality of transducers in each transducer group.

Further, a production method of an ultrasonic probe according to one aspect of the present invention is a production method of an ultrasonic probe including a plurality of transducers for transmitting and/or receiving ultrasonic waves, and the production method includes the steps of: (a) forming a multi-layered structure including a first electrode layer, a plurality of piezoelectric layers, at least one internal electrode layer, and a second electrode layer, on a principal surface of a backing material; (b) forming a plurality of grooves reaching the backing material on a principal surface of the multi-layered structure to separate the multi-layered structure into a plurality of transducers arranged in a first direction; (c) filling the plurality of grooves formed at step (b) with a conductive resin; (d) removing a part of the conductive resin filled at step (c); (e) filling the plurality of grooves, from which the conductive resin has been removed at step (d), with an insulating resin; (f) removing a part of the insulating resin filled at step (e); (g) repeating steps (c) to (f) as needed to form a first layer of conductive resin electrically connecting the first electrode layers of adjacent transducers with each other, a second layer of conductive resin electrically connecting the internal electrode layers of adjacent transducers with each other, and an insulating resin disposed in a predetermined region among the plurality of transducers; (h) forming a common electrode layer on the principal surface of the multi-layered structure; (i) forming at least one acoustic matching layer on the common electrode layer; and (j) forming a plurality of grooves reaching the backing material in the first direction on the principal surface of the multi-layered structure to separate each transducer into a plurality of transducers arranged in a second direction different from the first direction.

According to the present invention, it is possible to improve the electromechanical coupling coefficient and reduce the acoustic impedance by making the transducer have the 1-3 composite shape, and to reduce the electrical impedance by laminating the transducers. Thereby, it is possible to realize an ultrasonic probe having a high sensitivity and a wide band.

### BRIEF DESCRIPTION OF THE DRAWINGS

FIG. 1 is a plan view schematically showing an ultrasonic transducer array to be used in an ultrasonic probe according to a first embodiment of the present invention;

FIG. 2 is a front view showing an internal structure of the ultrasonic probe according to the first embodiment of the present invention;

FIGS. 3A and 3B are perspective enlarged views showing a multi-layered structure of a transducer;

FIG. 4 is a table showing materials of conductive resin and insulating resin;

FIGS. 5A to 5H are diagrams for illustrating a production method of the ultrasonic probe according to the first embodiment of the present invention;

FIG. 6 is a diagram for illustrating a variation of the production method of the ultrasonic probe according to the first embodiment of the present invention;

FIG. 7 is a front view showing an internal structure of an ultrasonic probe according to a second embodiment of the present invention;

FIG. 8 is a front view showing an internal structure of an ultrasonic probe according to a third embodiment of the present invention;

FIGS. 9A to 9C are diagrams showing images of a part of a cross-sectional face of a transducer group produced on a backing material photographed by a scanning electron microscope; and

FIGS. 10A and 10B are diagrams showing a measured result of electrical impedance characteristics in a transducer produced according to the third embodiment of the present invention.

### DESCRIPTION OF THE PREFERRED EMBODIMENTS

Hereinafter, embodiments of the present invention will be described in detail with reference to the drawings. Note that the same constituting elements are denoted by the same reference numerals and description thereof will be omitted.

FIG. 1 is a plan view schematically showing an ultrasonic transducer array to be used in an ultrasonic probe according to a first embodiment of the present invention. This transducer array includes a plurality of ultrasonic transducers 1 which expand and contract by a supply of a drive signal to transmit ultrasonic waves toward an object to be inspected and receive the ultrasonic waves reflected by the object to output an electric signal (detection signal). In FIG. 1, for showing an arrangement of the plurality of transducers 1, an upper electrode layer of the transducers 1 and insulating resin between the transducers 1 are omitted. Here, in particular, a transducer at the left end of the drawing is denoted by 1a and a transducer at the right end in the drawing is denoted by 1b among the plurality of transducers 1.

As shown in FIG. 1, while the plurality of transducers 1 is arranged in two dimensional manner, electrodes of the transducers 1 arranged in a line in the X axis direction (elevation direction) are connected in parallel with conductive resins 2 and the one line of the transducers 1 composes a transducer group 10 in which transducers operate at the same time. Accordingly, the plurality of transducer groups 10 arranged in the Y-axis direction (azimuth direction) composes a one-dimensional transducer array. By forming the transducers in the X axis direction by dividing a transducer in this manner, a piezoelectric material included in each of the transducers becomes to have the 1-3 composite shape and it is possible to increase the electromechanical coupling coefficient compared with a case the transducer is not divided in the X axis direction.

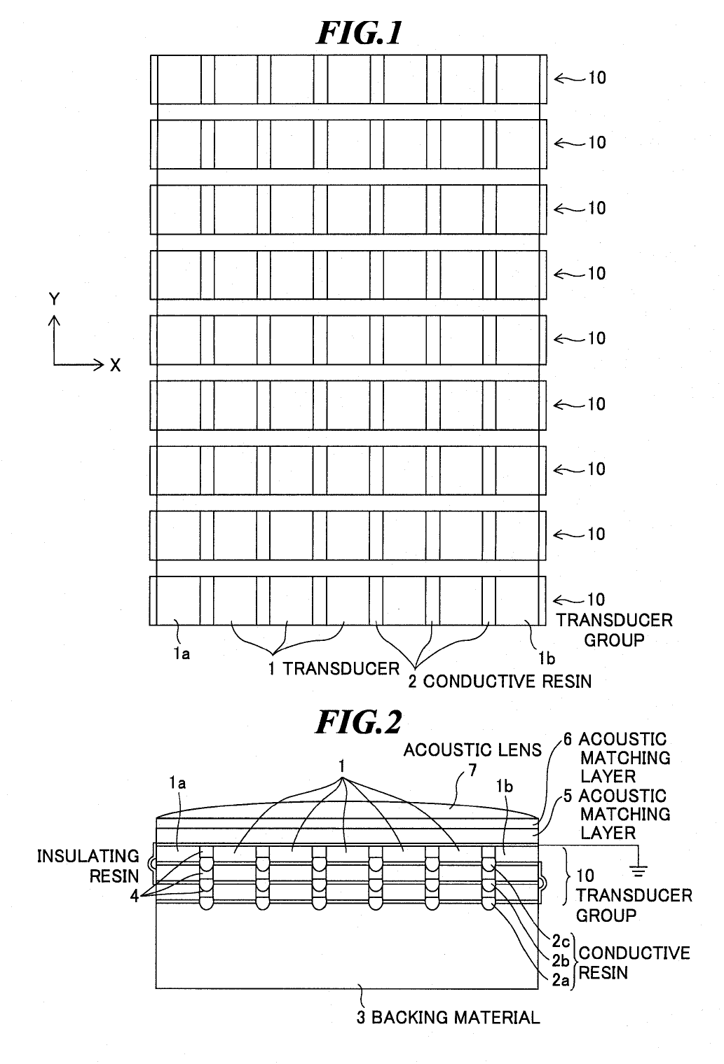

FIG. 2 is a front view showing an internal structure of the ultrasonic probe according to the first embodiment of the present invention. As shown in FIG. 2, the transducer group 10 composed of the one line of the transducers 1 is formed on a backing material 3. Each of the transducers 1 has a multi-layered structure and a plurality of layers of conductive resins 2a to 2c is disposed for connecting electrodes of each two adjacent transducers in the X direction in parallel. The backing material 3 is formed with a material having a large acoustic attenuation value such as epoxy resin containing ferrite powder, metal powder or PZT powder, or rubber containing ferrite powder, for example, and attenuates quickly an unnecessary ultrasonic wave generated in the plurality of transducers 1. Further, in regions where the conductive resins 2a to 2c do not exist among or around the plurality of transducers 1, insulating resin 4 is disposed for reducing interference between the transducers and for suppressing lateral vibration of the transducers to cause the transducers to vibrate only in the vertical direction.

At least one acoustic matching layer (two acoustic matching layers 5 and 6 are shown in FIG. 2) is formed on the plurality of transducers 1. Further, an acoustic lens 7 may be formed on the acoustic matching layer as needed. The acoustic matching layers 5 and 6 are formed from a material propagating ultrasonic waves efficiently such as Pyrex (registered trade mark) glass, epoxy resin containing metal powder, for example, and improve impedance matching between an object to be inspected such as a live body and the transducers 1. Thereby, ultrasonic waves transmitted from the transducers 1 can propagate efficiently through the object to be inspected. The acoustic lens 7 is formed from silicon rubber, for example, and focuses ultrasonic waves, transmitted from the plurality of transducers 1 and propagated through the acoustic matching layers 5 and 6, at a predetermined depth of the object. These parts 1 to 7 are stored in a casing and wirings drawn from the plurality of transducers 1 are connected to an electronic circuit in the ultrasonic diagnosing apparatus main body via a cable.

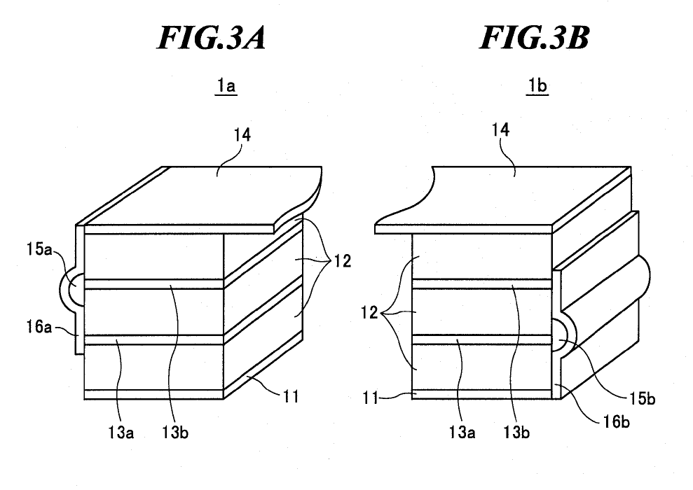

FIGS. 3A and 3B are enlarged perspective views showing the multi-layered structure of the transducers. FIG. 3A shows the transducer 1a at the left end of the transducer group 10 shown in FIG. 2, and FIG. 3B shows the transducer 1b at the right end of the transducer group shown in FIG. 2. Each of the transducers has a lower electrode layer 11, a plurality of piezoelectric layers 12, at least one internal electrode layer, and an upper electrode layer 14 typically connected commonly to the ground potential.

Preferably, the internal electrode layer includes at least one first internal electrode layer and at least one second internal electrode layer formed alternately sandwiching a piezoelectric layer. FIGS. 3A and 3B show a first internal electrode layer 13a and a second internal electrode layer 13b formed sandwiching the piezoelectric layer 12. Here, the lower electrode layer 11, the piezoelectric layer 12 at the bottom layer, and the internal electrode layer 13a constitute a first piezoelectric element, the internal electrode layer 13a, the piezoelectric layer 12 in the middle layer, and the internal electrode layer 13b constitute a second piezoelectric element, and the internal electrode layer 13b, the piezoelectric layer 12 on the top layer, and the upper electrode layer 14 constitute a third piezoelectric element.

Further, the transducer 1a at the left end in the drawing has a side surface insulating film 15a and a side surface electrode 16a. The side surface electrode 16a is connected to the internal electrode layer 13a and the upper electrode layer 14, and isolated from the internal electrode layer 13b by the side surface insulating film 15a. Also, the transducer 1b at the right end of the drawing has a side surface insulating film 15b and a side surface electrode 16b. The side surface electrode 16b is connected to the internal electrode layer 13b and the lower electrode layer 11 and isolated from the internal electrode layer 13a by the side surface insulating film 15b.

With reference to FIGS. 2, 3A and 3B, the lower electrode layers 11 of the plurality of transducers included in one of the transducer groups 10 are electrically connected with one another by the first layer of conductive resin 2a, the internal electrode layers 13a of the plurality of transducers included in one of the transducer groups 10 are connected with one another by the second layer of conductive resin 2b, and the internal electrode layers 13b of the plurality of transducers included in one of the transducer groups 10 are connected with one another by the third layer of conductive resin 2c.

Thereby, in each of the transducers, the laminated first to third piezoelectric elements are connected in parallel and capacitance of the transducer is increased to reduce the electrical impedance thereof. Furthermore, the plurality of transducers in one of the transducer groups 10 are connected in parallel and the capacitance of the transducer is further increased to reduce the electrical impedance thereof. Thereby, the electrical impedance matching with the electronic circuit in the ultrasonic diagnosing apparatus main body is improved.

Further, by making the piezoelectric element have a composite piezoelectric material, a ratio of the volume of the piezoelectric element to the volume of the whole transducer is reduced, that is, a volume ratio of the piezoelectric material, which is a source of generating heat, is reduced. Thereby, it is possible to suppress an increase of the surface temperature of the ultrasonic probe. In particular, when the piezoelectric element has the multi-layered structure, a generated heat amount is considerably larger than in a case where the piezoelectric element has a single layer structure and the use of the composite piezoelectric material is more effective to suppress the temperature increase.

In the present embodiment, piezoelectric ceramic is used as the piezoelectric material. The piezoelectric ceramic has a high electromechanical energy conversion capability, and thereby can generate a strong ultrasonic wave capable of reaching a deep part of the human body and has a high receiving sensitivity. Specific usable materials include PTZ (lead zirconate titanate: Pb(Ti, Zr)O₃), a metamorphic material having a similar perovskite-type crystal structure, a material generally called a relaxor-type material, etc.

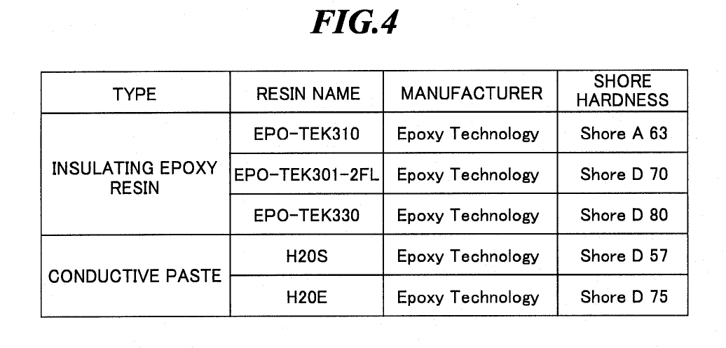

Further, in the present embodiment, a hardness of the conductive resin 2 is higher than that of the insulating resin 4. Materials shown in FIG. 4 are used for the conductive resin and the insulating resin, for example. Usable insulating materials include epoxy-type resins such as EPO-TEK310, EPO-TEK301-2FL, EPO-TEK330, etc. produced by Epoxy Technology. On the other hand, usable conductive resins include conductive pastes such as H20S, H20E, etc. produced by the Epoxy Technology.

FIG. 4 shows shore hardness data of these materials. The shore hardness represents a measured insert depth value of a predetermined insert needle inserted into a material under a condition prescribed in the ISO868, where the D-standard prescribes a higher hardness than the A-standard and a larger number represents a higher hardness in each of the standards. For example, when the EPO-TEK310 is selected for the insulating resin among the materials shown in FIG. 4, the H20S or the H20E may be selected for the conductive resin. Note that the shore hardness is also prescribed in ASTM D2240-97el (Standard Test Method for Rubber Property-Durometer Hardness), JIS K7215 (Testing Method for Durometer Hardness of Plastics), etc.

In a case the transducer is formed in a pillar shape and made to have the 1-3 composite shape, there arises such a problem that a vibration shift of the transducer becomes large, and thereby, a desired electromechanical conversion property cannot be obtained and further a plurality of resonance peaks are generated, even if soft resin is filled in spaces among the plurality of transducers. On the other hand, when a resin with a high hardness is filled in the whole of the spaces among the plurality of transducers, the vibration of the transducer is suppressed and desired electromechanical conversion characteristics cannot be obtained similarly.

Accordingly, in the present embodiment, a resin with a high hardness is partially included in a soft resin to realize a structure which does not suppress the vibration while preventing the vibration shift of the transducer. That is, as shown in FIG. 2, the conductive resin 2, which has a comparatively high hardness, and the insulating resin 4, which has a comparatively low hardness, are disposed among the plurality of transducers 1 for realizing the above structure. Also, the conductive resin 2, which has a comparatively high hardness, is inserted as a stake in the grooves formed in the backing material 3 and the vibration shift of the transducer is further suppressed.

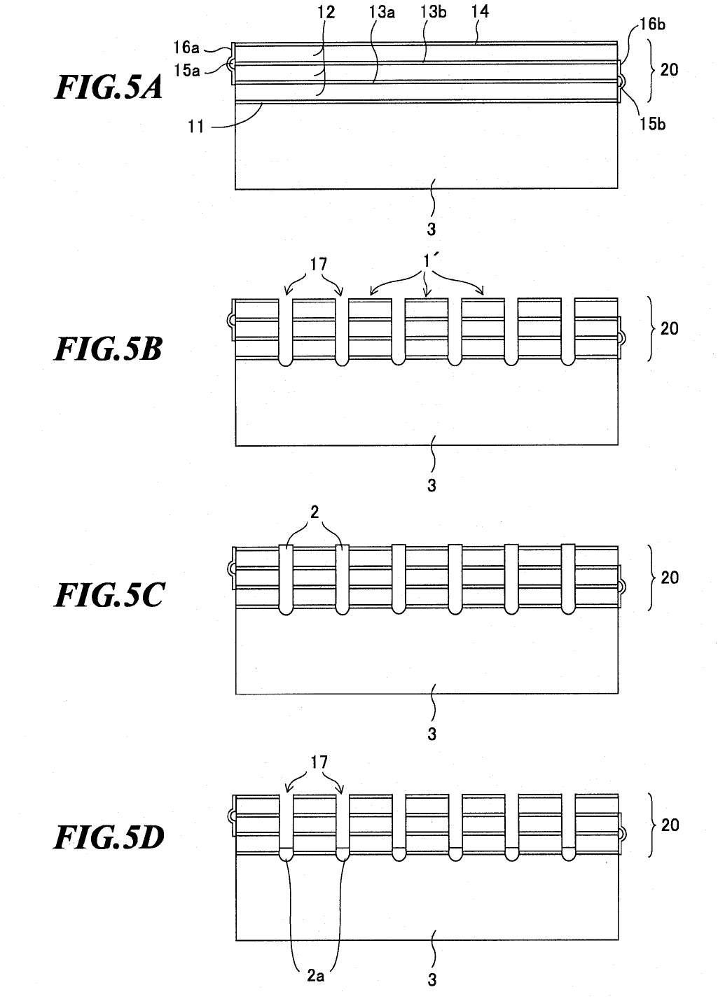

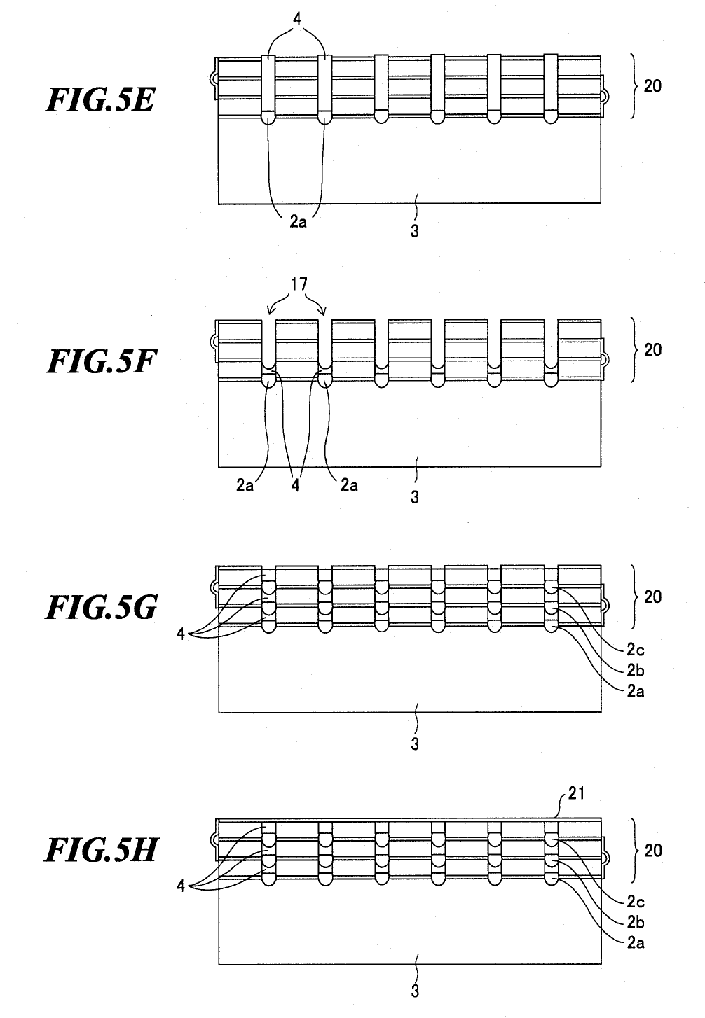

Next, a production method of the ultrasonic probe according to the first embodiment of the present invention will be described. FIGS. 5A to 5H are diagrams for illustrating the production method of the ultrasonic probe according to the first embodiment of the present invention.

At the first step, as shown in FIG. 5A, a multi-layered structure 20 including the lower electrode layer 11, the plurality of piezoelectric layers 12, the internal electrode layers 13a and 13b, and the upper electrode layer 14 is formed on the principal surface of backing material 3.

Further, the side surface insulating film 15a covering the internal electrode layer 13b is formed on the left (in the drawing) side surface of the multi-layered structure 20, and the side surface insulating film 15b covering the internal electrode layer 13a is formed on the right (in the drawing) side surface of the multi-layered structure 20, by an electro-deposition method, dispense method, print method, or the like. For a material of the side surface insulating films 15a and 15b, there is used epoxy resin, glass paste, or the like.

Subsequently, the side surface electrode 16a connected to the internal electrode layer 13a and the upper electrode layer 14 is formed on the left (in the drawing) side surface of the multi-layered structure 20, and the side surface electrode 16b connected to the internal electrode layer 13b and the lower electrode layer 11 is formed on the right (in the drawing) side surface of the multi-layered structure 20, by a plating method, sputtering method, or the like. For a material of the side surface electrodes 16a and 16b, there is used a metal such as platinum, gold, palladium, nickel, chromium, titanium, cobalt, etc, and an alloy containing at least one of the above metals or the like.

At the second step, as shown in FIG. 5B, the plurality of grooves 17 reaching the backing material 3 is formed on the principal surface of the multi-layered structure 20 in the azimuth direction (Y axis direction in FIG. 1). Thereby, the multi-layered structure 20 is divided into the plurality of transducers 1′ having a long dimension in the Y axis direction.

At the third step, as shown in FIG. 5C, the plurality of grooves 17 is filled with the conductive resin 2. Further, at the fourth step, as shown in FIG. 5D, at least a part of the conductive resin 2 is cut by dicing along the plurality of grooves 17 to be removed. Thereby, the first layer of conductive resin 2a is formed from the bottom of the bottom piezoelectric layer 12 to a height of about one third of the thickness thereof.

At the fifth step, as shown in FIG. 5E, the insulating resin 4 is filled at the portions of the plurality of grooves 17, from which the conductive resin 2 is removed at the fourth step. Further, at the sixth step, as shown in FIG. 5F, at least a part of the insulating resin 4 is cut by dicing along the plurality of grooves 17 to be removed.

By repeating the third step to the sixth step as needed and by cutting protrusions of the insulating resin 4 at the last sixth step, the structure having the first to third layers of the conductive resin 2a to 2c and the insulating resin 4 is completed as shown in FIG. 5G. Also, since parts of the upper electrode layer 14 have been cut by the dicing, a common electrode layer 21 is formed on the principal surface of the multi-layered structure 20 as shown in FIG. 5H to supplement the upper electrode layer 14.

Further, at least one acoustic matching layer is formed on the common electrode layer 21 and a plurality of grooves reaching the backing material 3 are formed on the principal surface of the multi-layered structure 20, on which the acoustic matching layer has been formed, in a second direction, e.g., elevation direction (X axis direction in FIG. 1), different from the first direction. Thereby, each transducer group 10 is formed including the plurality of transducers 1 arranged in the X axis direction as shown in FIG. 1. After that, wiring to the electrode layers is carried out and the acoustic lens 7 is attached to complete the ultrasonic probe shown in FIG. 2.

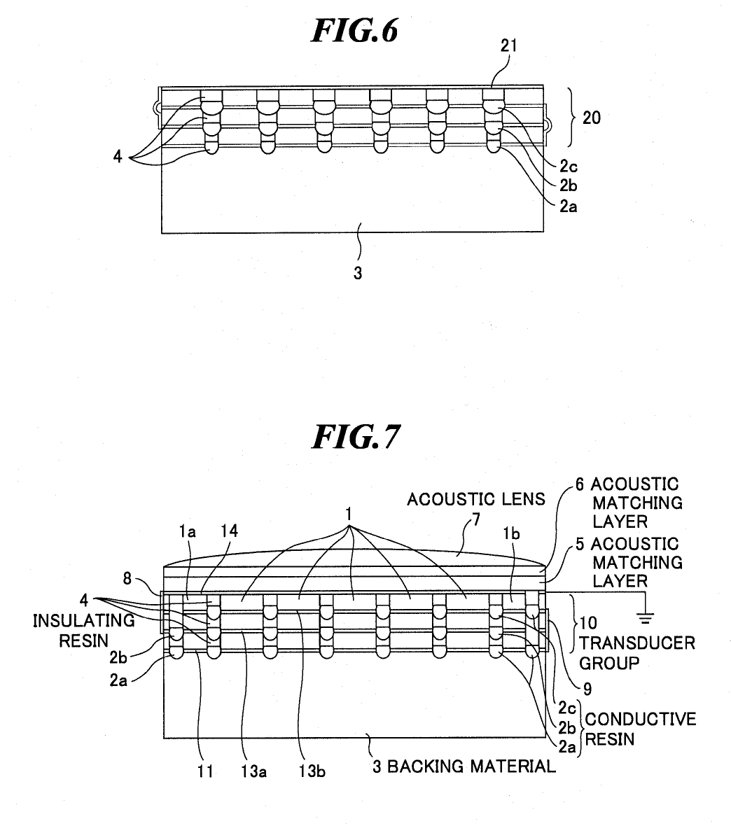

As a variation of the above-mentioned production method, the width of the grooves 17 may be increased step by step as shown in FIG. 6, by increasing the width of a dicing blade step by step or by carrying out a multiple dicing processing at the sixth step (FIG. 5F) of cutting out parts of insulating resin 4 by dicing. Thereby, the widths of the first to third layers of the conductive resins 2a to 2c are increased step by step. As a result, a side surface of the transducer becomes to have a trapezoidal shape having larger widths at lower side and less width at upper side in the drawing, and the vibration of the transducer becomes stabilized. Also, the acoustic impedance of the transducer is reduced step by step toward the object to be inspected, and thereby, the acoustic impedance matching between the object such as the human body and the transducer is improved to upgrade the performance of the ultrasonic probe such as the sensitivity, band width or the like.

Next, a second embodiment of the present invention will be described.

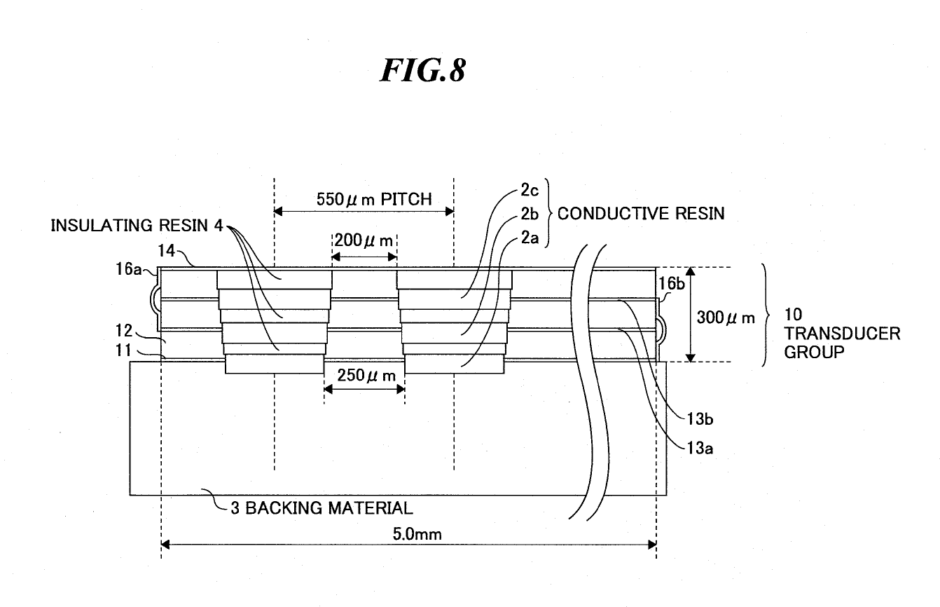

FIG. 7 is a front view showing an internal structure of an ultrasonic probe according to the second embodiment of the present invention. In the second embodiment, as shown in FIG. 7, the third layer of conductive resin 2c is not formed in the left end groove in the drawing while only the first layer of conductive resin 2a and the second layer of conductive resin 2b are formed therein, and the second layer of conductive resin 2b is not formed in the right end groove in the drawing while only the first layer of conductive resin 2a and the third layer of conductive resin 2c are formed therein, in each transducer group 10.

Also, the internal electrode layers include at least one first internal electrode layer and at least one second internal electrode layer formed sandwiching a piezoelectric layer. FIG. 7 shows the first internal electrode layer 13a and the second internal electrode layer 13b formed sandwiching the piezoelectric layer 12.

A side surface electrode 8 is formed on the left (in the drawing) side surface of each transducer group 10 to be electrically connected to the internal electrode layers 13a and 13b and the upper electrode layer 14, and a side surface electrode 9 is formed on the right (in the drawing) side surface of each transducer group 10 to be electrically connected to the internal electrode layers 13a and 13b and the lower electrode layer 11.

At the left (in the drawing) side end of each transducer group 10, a groove is formed to separate at least the internal electrode layer 13b, and insulating resin 4 is filled in the gap between the separated internal electrode layer 13b. Also, at the right (in the drawing) side end of each transducer group 10, a groove is formed to separate at least the internal electrode layer 13a, and insulating resin 4 is filled in the gap between the separated internal electrode layer 13a. Other points of the structure are the same as those in the first embodiment.

In this manner, the second embodiment acquires the electrode connection in the multi-layered structure by changing the configuration of the conductive resins 2a to 2c and the insulating resin 4 in the grooves at the left end and right end in the drawing, without forming the side surface insulating films 15a and 15b shown in FIG. 5A.

Next, there will be described a production method of the ultrasonic probe according to the second embodiment of the present invention. The ultrasonic probe according to the second embodiment is produced by a production method obtained by a partial change of the production method of the ultrasonic probe according to the first embodiment, which has been described with reference to FIGS. 5A to 5H.

At the first step, as shown in FIG. 5A, the multi-layered structure 20 including the lower electrode layer 11, the plurality of piezoelectric layers 12, the internal electrode layers 13a and 13b, and the upper electrode layer 14 is formed on the principal surface of the backing material 3. Note that the side surface insulating films 15a and 15b shown in FIG. 5A are not formed, and as shown in FIG. 7, the side surface electrode 8 is formed on the left (in the drawing) side surface of the multi-layered structure to be connected to the internal electrode layers 13a and 13b and the upper electrode layer 14 and also the side surface electrode 9 is formed on the right (in the drawing) side surface of the multi-layered structure to be connected to the internal electrode layers 13a and 13b and the lower electrode layer 11.

Also, at the second step, as shown in FIG. 7, the groove separating at least the internal electrode layer 13b is formed in the azimuth direction (Y axis direction in FIG. 1) at the left (in the drawing) side end of the multi-layered structure, and the groove separating at least the internal electrode layer 13a is formed in the azimuth direction in the right (in the drawing) side end of the multi-layered structure.

By further repeating the third to sixth steps as needed, the first to third layers of the conductive resin 2a to 2c and the insulating resin 4 are formed. Here, as shown in FIG. 7, the insulating resin 4 is filled in the gap of the separated internal electrode layer 13a in the left (in the drawing) side end groove of the multi-layered structure, and the insulating resin 4 is filled in the gap of the separated internal electrode layer 13b at the right (in the drawing) side end groove of the multi-layered structure.

Next, a third embodiment of the present invention will be described.

FIG. 8 is a front view showing an internal structure of an ultrasonic probe according to the third embodiment of the present invention. In the third embodiment, a specific shape of the transducer group in the ultrasonic probe according to the first embodiment is determined to actually produce the transducer group and the electrical impedance characteristics of the transducer are measured.

For the backing material 3, the present embodiment employs chlorinated polyethylene mixed with ferrite powder, which has an acoustic impedance of about 6 MRayl. Also, Ag paste H20S produced by Epoxy Technology is used for the conductive resins 2a to 2c, and epoxy type resin EPO-TEX330 produced by Epoxy Technology is used for the insulating resin 4.

For the piezoelectric material 12, three layers of piezoelectric ceramic (specifically, PZT), each layer of which is formed according to a green sheet method and has a thickness of 100 μm, are stacked sandwiching the internal electrode layers 13a and 13b. The relative dielectric constant of this piezoelectric ceramic is 4,500 at 1 kHz. Also, volume ratio of the piezoelectric material 12 to the resin portion (conductive resins 2a to 2c and insulating resin 4) is about 1:2.

In FIG. 8, the length (in the elevation direction) of each transducer group 10 is 5.0 mm, the width (in the azimuth direction) thereof is 0.11 mm (110 μm), and the height thereof is 0.3 mm (300 μm). Also, the arrangement pitch of the conductive resins 2a to 2c and the insulating resin 4 is 550 μm, the length of each electrode of the lower electrode layer 11 is 250 μm, and the length of each electrode of the upper electrode layer 14 is 200 μm. Each of the side surface electrodes 16a and 16b has a two-layered structure of chromium and gold layers and the total thickness thereof is about 450 nm.

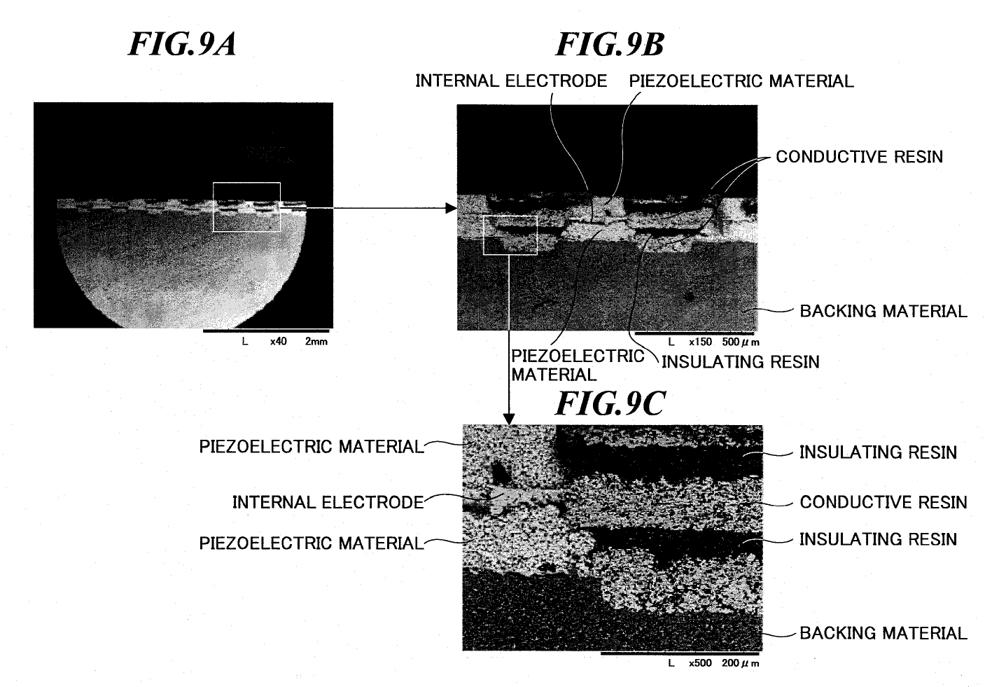

FIGS. 9A to 9C are diagrams showing images of a part of a cross-sectional face of a transducer group produced on a backing material photographed by a scanning electron microscope (SEM). FIG. 9A shows a transducer group including seven transducers. FIG. 9B is an enlarged view showing a part of the transducer group shown in FIG. 9A. As shown in FIG. 9B, each transducer has an internal electrode between piezoelectric materials, and a conductive resin (silver paste H20S) is disposed as enclosed by insulating resins (EPO-TEK330) in order to connect internal electrodes of neighboring two transducers. FIG. 9C is an enlarged view showing a part of the resin portion and the transducer shown in FIG. 9B. In FIG. 9C, it is apparent that the internal electrode and the conductive rein are connected in a good condition.

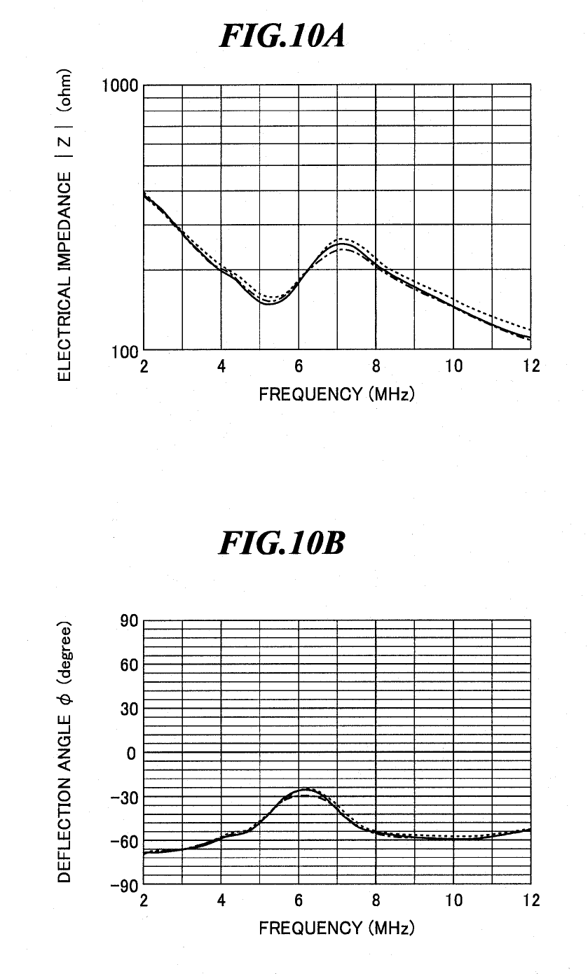

FIGS. 10A and 10B are diagrams showing a measured result of the electrical impedance characteristics of a transducer produced according to the third embodiment of the present invention. In FIGS. 10A and 10B, the horizontal axes represent frequencies (MHz) and the vertical axis of FIG. 10A represents absolute values of the electrical impedance |Z| (ohm), and the vertical axis of FIG. 10B represents deflection angles φ (degree) of the electrical impedance. The number of sample transducers is three for the measurement. An apparent relative dielectric constant of the piezoelectric material is calculated to be about 12,570 based on the measured values of the electrical impedance of the transducers at 2 MHz.

When a piezoelectric material having a relative dielectric constant of 4,500 and a resin having a relative dielectric constant of about 5 are made to be a composite by a volume ratio of 1:2 as in the present embodiment, the relative dielectric constant of the composite material becomes about 1,500. Also, generally in a transducer having a multi-layered structure produced by stacking N layers of piezoelectric materials, a static capacitance thereof becomes N² times that of a single layer transducer having the same size, and thereby the apparent relative dielectric constant thereof, converted into that of the single layer transducer, is considered to become also N² times that of the single layer transducer. Accordingly, when a three-layer structured transducer is produced by use of a composite material having a relative dielectric constant of 1,500, an apparent dielectric constant thereof is predicted to become 1,500×3²=13,500. In the present embodiment, the measured value of the apparent relative dielectric constant is 12,570 and this value is 93% of the predicted value showing a good agreement with the prediction. Also, the measured value of the deflection angle in the electrical impedance is the same as predicted in the present embodiment and these results show that the three-layer structured transducer is successfully produced by use of the composite material.

According to the above embodiments, it is possible to improve the electromechanical coupling coefficient and to reduce the acoustic impedance at the same time by making a transducer have the 1-3 composite shape, and to reduce the electrical impedance by making the transducer have a multi-layered structure, resulting in realizing an ultrasonic probe having a high sensitivity and a wide band. As a result, an image quality or a diagnosis performance is improved compared with a conventional ultrasonic probe in the harmonic imaging or the contrast Doppler imaging. Also, heat generated by the transducer can be reduced. Further, it is possible to realize a structure which does not suppress vibration of the transducer while preventing the vibration shift thereof by disposing conductive resin having a comparatively high hardness and insulating resin having a comparatively low hardness among a plurality of transducers. Note that the present invention can be applied to any shape of the ultrasonic probe such as a sector type, linear type, convex type, or radial type.

1. An ultrasonic probe including a plurality of transducers for transmitting and/or receiving ultrasonic waves, said ultrasonic probe comprising:
a backing material;
a transducer array in which a plurality of transducers are arranged in a first direction to compose a transducer group and a plurality of transducer groups are arranged in a second direction different from the first direction, each transducer having a multi-layered structure including a first electrode layer formed on a principal surface of said backing material, a plurality of piezoelectric layers, at least one internal electrode layer, and a second electrode layer common in each transducer group;
a first layer of conductive resin electrically connecting the first electrode layers of adjacent transducers with each other in each transducer group;
a second layer of conductive resin electrically connecting the internal electrode layers of adjacent transducers with each other in each transducer group; and
an insulating resin disposed in a predetermined region among said plurality of transducers in each transducer group.

2. The ultrasonic probe according to claim 1, wherein said first layer of conductive resin and said second layer of conductive resin have degrees of hardness higher than that of said insulating resin.

3. The ultrasonic probe according to claim 1, wherein said first layer of conductive resin has a degree of hardness higher than that of said second layer of conductive resin.

4. The ultrasonic prove according to claim 1, wherein a plurality of grooves are formed on the principal surface of said backing material and a part of said first layer of conductive resin is filled inside of said plurality of grooves.

5. The ultrasonic probe according to claim 1, wherein said second layer of conductive resin is formed in a region wider than a region where said first layer of conductive resin is formed.

6. The ultrasonic probe according to claim 1, wherein each transducer includes at least one first internal electrode layer and at least one second electrode layer formed alternately sandwiching a piezoelectric layer, and said ultrasonic probe further comprises:
a first side surface insulating film formed on a first side surface of each transducer group, for covering said second internal electrode layer;
a second side surface insulating film formed on a second side surface of each transducer group, for covering said first internal electrode layer;
a first side surface electrode formed on the first side surface of each transducer group, connected to said first internal electrode layer and said second electrode layer, and insulated from said second internal electrode layer by said first side surface insulating film; and
a second side surface electrode formed on the second side surface of each transducer group, connected to said second internal electrode layer and said first electrode layer, and insulated from said first internal electrode layer by said second side surface insulating film.

7. The ultrasonic probe according to claim 1, wherein each transducer includes at least one first internal electrode layer and at least one second internal electrode layer formed alternately sandwiching a piezoelectric layer, said ultrasonic probe further comprises:
a first side surface electrode formed on a first side surface of each transducer group, and connected to said first and second internal electrode layers and said second electrode layer; and
a second side surface electrode formed on a second side surface of each transducer group, and connected to said first and second internal electrode layers and said first electrode layer;
wherein a groove is formed to separate at least said second internal electrode layer at an end of the first side surface side of each transducer group and said insulating resin is filled in a gap of the separated second internal electrode layer, and a groove is formed to separate at least said first internal electrode layer at an end of the second side surface side of each transducer group and said insulating resin is filled in a gap of the separated first internal electrode layer.

8. A production method of an ultrasonic probe including a plurality of transducers for transmitting and/or receiving ultrasonic waves, said production method comprising the steps of:
(a) forming a multi-layered structure including a first electrode layer, a plurality of piezoelectric layers, at least one internal electrode layer, and a second electrode layer, on a principal surface of a backing material;
(b) forming a plurality of grooves reaching said backing material on a principal surface of said multi-layered structure to separate said multi-layered structure into a plurality of transducers arranged in a first direction;
(c) filling said plurality of grooves formed at step
(b) with a conductive resin;
(d) removing a part of said conductive resin filled at step (c);
(e) filling said plurality of grooves, from which said conductive resin has been removed at step (d), with an insulating resin;
(f) removing a part of said insulating resin filled at step (e);
(g) repeating steps (c) to (f) as needed to form a first layer of conductive resin electrically connecting the first electrode layers of adjacent transducers with each other, a second layer of conductive resin electrically connecting the internal electrode layers of adjacent transducers with each other, and an insulating resin disposed in a predetermined region among said plurality of transducers;
(h) forming a common electrode layer on the principal surface of said multi-layered structure;
(i) forming at least one acoustic matching layer on said common electrode layer; and
(j) forming a plurality of grooves reaching said backing material in the first direction on the principal surface of said multi-layered structure to separate each transducer into a plurality of transducers arranged in a second direction different from the first direction.

9. The production method according to claim 8, wherein said first layer of conductive resin and said second layer of conductive resin have degrees of hardness higher than that of said insulating resin.

10. The production method according to claim 8, wherein said first layer of conductive resin has a degree of hardness higher than that of said second layer of conductive resin.

11. The production method according to claim 8: wherein said multi-layered structure includes at least one first internal electrode layer and at least one second internal electrode layer formed alternately sandwiching a piezoelectric layer, and step (a) includes:
forming a first side surface insulating film covering said second internal electrode layer on a first side surface of said multi-layered structure, and forming a second side surface insulating film covering said first internal electrode layer on a second side surface of said multi-layered structure; and
forming a first side surface electrode on the first side surface of said multi-layered structure, said first side surface electrode being connected to said first internal electrode layer and said second electrode layer and insulated from said second internal electrode layer by said first side surface insulating film, and forming a second side surface electrode on the second side surface of said multi-layered structure, said second side surface electrode being connected to said second internal electrode layer and said first electrode layer and insulated from said first internal electrode layer by said second side surface insulating film.

12. The production method according to claim 8: wherein said multi-layered structure includes at least one first internal electrode layer and at least one second internal electrode layer formed alternately sandwiching a piezoelectric layer;
step (a) includes forming a first side surface electrode connected to said first and second internal electrode layers and said second electrode layer on a first side surface of said multi-layered structure, and forming a second side surface electrode connected to said first and second internal electrode layers and said first electrode layer on a second side surface of said multi-layered structure;
step (b) includes forming a groove to separate at least said second internal electrode layer at an end of the first side surface side of said multi-layered structure, and forming a groove to separate at least said first internal electrode layer at an end of the second side surface side of said multi-layered structure; and
step (g) includes filling a gap of the separated first internal electrode layer with said insulating resin, and filling a gap of the separated second internal electrode layer with said insulating resin.
